(19) United States
(12) Patent Application Publication
(10) Pub. No.: US 2012/0038412 A1
(43) Pub. Date: Feb. 16, 2012

(54) SWITCH DEVICE

(75) Inventor: SEN-LUNG HUANG, Tu-Cheng (TW)

(73) Assignee: HON HAI PRECISION INDUSTRY CO., LTD., Tu-Cheng (TW)

(21) Appl. No.: 12/949,820

(22) Filed: Nov. 19, 2010

(30) Foreign Application Priority Data
Aug. 16, 2010 (CN) 201020293139.7

(51) Int. Cl. H03K 17/60

(52) U.S. Cl. 327/482

(57) ABSTRACT

A switch device executes a multi-state function to a computer. The computer has a system on chip. The switch device comprises a switch, a power output circuit, a control circuit, a timer circuit and an interface circuit of the system on chip. A user can press the switch, the control circuit controls the power output circuit to output a control signal to the system on chip for controlling the computer turning on or going into suspend state. When the user continues to press the switch, the timing circuit will execute a timer function to the switch device.

### BACKGROUND

1. Technical Field

Embodiments of the present disclosure relate to switches, and more particularly to a switch device for computers.

2. Description of Related Art

Microcontrollers in computers are often programmed to output corresponding control signals by which the computers are able to be turned off or enter a suspend mode to conserve power. However, costs of such microcontrollers are high.

### BRIEF DESCRIPTION OF THE DRAWINGS

FIG. 1 is a block diagram of one embodiment of a switch device in connection with a computer.

FIG. 2 is an electronic circuit diagram of one embodiment of the switch device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

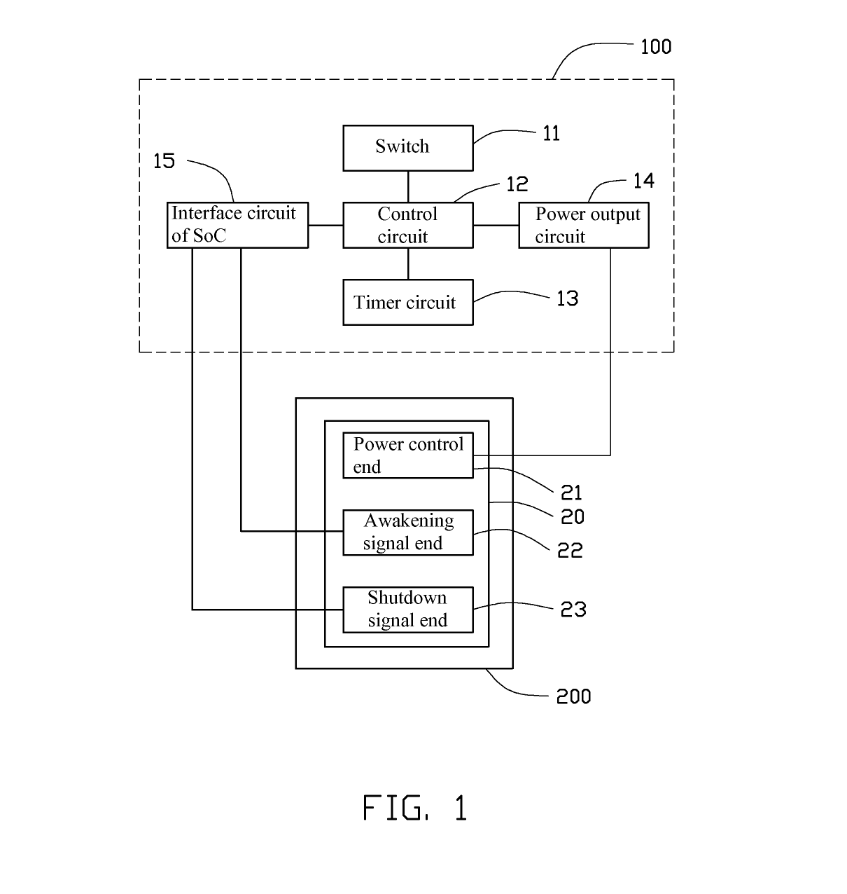

FIG. 1 is a block diagram of one embodiment of a switch device 100 in connection with a computer 200. The switch device 100 includes a switch 11, a control circuit 12, a timer circuit 13, a power output circuit 14 and an interface circuit of system on chip (SoC) 15. The control circuit 12 electrically connects to the switch 11, the timer circuit 13, the power output circuit 14 and the interface circuit of system on chip 15.

The computer 200 includes a SoC 20. The SoC 20 integrates all components of a computer or other electronic system into a single integrated circuit (chip). It may contain digital, analog, and mixed-signal functions. The SoC 20 is on a single chip substrate. In one embodiment, The SoC 20 includes a power control end 21, an awakening signal end 22 and a shutdown signal end 23.

The control circuit 12 is operable to control the power output circuit 14 outputting a power control signal to the SoC 20 of the computer 200 to control a power status of the computer 200. For example, the control circuit 12 can control the power output circuit 14 outputting a shutdown signal to the SoC 20 to turn off the computer 200. In one embodiment, the control circuit 12 comprises a npn type 1, 3 transfer resistor Q1, a npn type 2, 3 transfer resistor Q2 and a npn type 3, 3 transfer resistor Q3. Each npn type transfer transistor has terminals labeled base, collector, and emitter. The base of the npn type 1, 3 transfer resistor Q1 connects to a moving contact point S2 of the switch 11. One end of a resistor R2 connects to the base of the npn type 1, 3 transfer resistor Q1. The other end of the resistor R2 connects to a first point J1. The emitter of the npn type 1, 3 transfer resistor Q1 connects to the first point J1. The collector of the npn type 1, 3 transfer resistor Q1 connects to the collector of the npn type 2, 3 transfer resistor Q2 through a resistor R3. The collector of the npn type 1, 3 transfer resistor Q1 further connects to the ground through series resistors R4 and R5.

The base of the npn type 2, 3 transfer resistor Q2 connects to a second point J2 through a resistor R6. The emitter of the npn type 2, 3 transfer resistor Q2 connects to the ground. The collector of the npn type 2, 3 transfer resistor Q2 further connects to the ground through a capacitor C1. The capacitor C1 is operable to filter an alternating current outputted from the collector of the npn type 1, 3 transfer resistor Q1. The emitter of the npn type 3, 3 transfer resistor Q3 connects to the ground. The collector of the npn type 3, 3 transfer resistor Q3 connects to the power output circuit 14. The base of the npn type 3, 3 transfer resistor Q3 connects to the collector of the npn type 2, 3 transfer resistor Q2. The base of the npn type 3, 3 transfer resistor Q3 is operable to amplify a voltage outputted from the npn type 1, 3 transfer resistor Q1 to the power output circuit 14.

The timer circuit 13 is operable to execute a timer function to the switch device 100. In one embodiment, the timer circuit 13 includes a resistor R7, a set of parallel capacitors C2, C3. One end of the resistor R7 connects to the first point J1 and the second point J2. One end of the set of the parallel capacitors C2, C3 connects to the second point J2 and the other end of the set of parallel capacitors C2, C3 connects to the ground.

The power output circuit 14 is operable to output the power control signal to the power control end 21 of the computer 200. The power output circuit 14 includes a npn type 4, 3 transfer resistor Q4. The base of the npn type 4, 3 transfer resistor Q4 connects to the collector of the npn type 3, 3 transfer resistor Q3 through a resistor R8. The base of the npn type 4, 3 transfer resistor Q4 further connects to the base of the npn type 1, 3 transfer resistor Q1 through a resistor R9 and a capacitor C4 being in series connection. The emitter of the npn type 4, 3 transfer resistor Q4 connects to a first power VDD and connects to a resistor R9 and the capacitor C4 being in series connection. The collector of the npn type 4, 3 transfer resistor Q4 connects to the power control end 21. The power control end 21 is operable to provide an electronic power to the computer 200. In addition, the collector of the npn type 4, 3 transfer resistor Q4 connects to the series resistors R4, R5 and feedbacks the power control signal to the control circuit 12.

The interface circuit of system on chip 15 includes a npn type 5, 3 transfer resistor Q5. The base of npn type 5, 3 transfer resistor Q5 connects to the ground through the base of a resistor R10 and connects to the first point J1 through a resistor R11. The collector of the npn type 5, 3 transfer resistor Q5 connects to a second power VCC through a resistor R12. In addition, the npn type 5, 3 transfer resistor Q5 further connects to an awakening signal end 22 through a resistor R13. The awakening signal end 22 is operable to output an awakening signal to the SoC 20 to awaken the computer 200 in the suspend mode.

The shutdown signal end 23 connects to the ground through a set of series resistors R14 and R15. The second point J2 connects to the resistors R14 and R15 and is positioned between the resistors R14 and R15. The shutdown signal end 23 can send a shutdown signal to the control circuit 12 through the resistor R14.

The switch 11 is operable to interrupt the flow of electrons in a circuit that are either completely on (“closed”) or completely off (“open”). In one embodiment, the switch 11 comprises a fixed contact point S1 and a moving contact point S2. Wherein, the fixed contact point S1 connects to the first power VDD through a resistor R1. The moving contact point S2 connects to the control circuit 12. In other embodiments, users can connect the switch 11 in a short time to force the computer 200 to run the suspend mode or a booting mode. Furthermore, users can connect the switch 11 in a long time connection to force the computer 200 to run a shutdown mode.

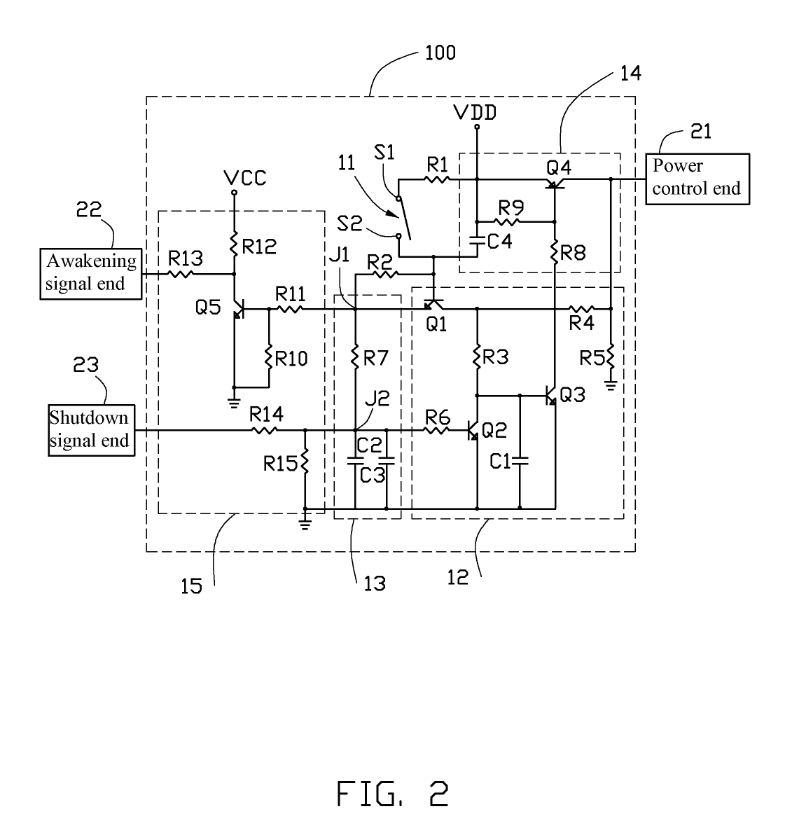

As shown in FIG. 2, an electronic circuit diagram of the switch device 100 is shown. The npn type 1, 3 transfer resistor Q1 of the control circuit 12 is connected if the switch 11 is connected. Then the collector of npn type 1, 3 transfer resistor Q1 outputs a high level voltage. The moving contact point S2 of the switch 11 connects to the first point J1 through the resistor R2 and the voltage of the first point J1 is the high level voltage. The parallel capacitors C2, C3 start to be charged because of the high level voltage of the first point J1. Because the switch 11 is not connected continuously, the parallel capacitors C2, C3 are not charged continuously. Therefore, the voltage of the base of npn type 2, 3 transfer resistor Q2 is small than a start voltage of the npn type 2, 3 transfer resistor Q2. Accordingly, the npn type 2, 3 transfer resistor Q2 is not active.

In addition, the collector of the npn type 1, 3 transfer resistor Q1 connects to the base of the npn type 3, 3 transfer resistor Q3 through the resistor R3. Then the npn type 3, 3 transfer resistor Q3 is in an electric conduction. The npn type 3, 3 transfer resistor Q3 amplifies the voltage of the collector of the npn type 1, 3 transfer resistor Q1 to the npn type 4, 3 transfer resistor Q4. Then the npn type 4, 3 transfer resistor Q4 is in the electric conduction. Accordingly, the collector of the npn type 4, 3 transfer resistor Q4 outputs a high level voltage (power control signal) to the power control end 21. The high level voltage can be a power to the SoC 20. The SoC 20 is then active and controls the computer 200 operating in the booting mode or the suspend operation.

The voltage of the power control end 21 is through the resistors R4, R3 to feedback to the base of the npn type 3, 3 transfer resistor Q3. The npn type 3, 3 transfer resistor Q3 and the npn type 4, 3 transfer resistor Q4 are in the electric conduction continually. The electric conduction makes the control circuit 12 having a memory function to the SoC 20. In one embodiment, even if switch 11 is broken immediately after the electric conduction, the control circuit 12 can still output the power control signal to the SoC 20.

In other embodiments, the computer 200 is in the suspend mode before connecting the switch 11 and then connects the switch 11. The high level voltage of the first point J1 forces the npn type 5, 3 transfer resistor Q5 being in the electric conduction. The electric conduction of the npn type 5, 3 transfer resistor Q5 makes an input voltage of the awakening signal end 22 being a low level voltage. If the SoC 20 is in a continuous supply condition, the control circuit 12 also can output the awakening signal to the SoC 20 to awaken the computer 200 in the suspend mode.

In other embodiments, if the switch 11 is connected continually, the high level voltage of the first point J1 makes the parallel capacitors C2, C3 being charged continually. Until the voltage between the two ends of the parallel capacitors C2, C3 equals to the start voltage of the npn type 2, 3 transfer resistor Q2, the npn type 2, 3 transfer resistor Q2 is then in the electric conduction. At the moment, the voltage of the base of the npn type 3, 3 transfer resistor Q3 is low level voltage. The npn type 3, 3 transfer resistor Q3 and the npn type 4, 3 transfer resistor Q4 are not active. The voltage outputted from the collector of the npn type 4, 3 transfer resistor Q4 to the power control end 21 is in the low level voltage (the shutdown signal). Therefore, the power of the SoC 20 is broken and the computer 200 is shutdown.

In other embodiments, the SoC 20 can set a predetermine time period for controlling the computer 200. For example, If the computer 200 is active and operates over the predetermine time period. The SoC 20 outputs the high level voltage to the npn type 2, 3 transfer resistor Q2 through the shutdown signal end 23. The npn type 2, 3 transfer resistor Q2 is then in the electric conduction. The npn type 3, 3 transfer resistor Q3 and the npn type 4, 3 transfer resistor Q4 are broken and the computer 200 is shutdown.

In alternative embodiments, instead of a microcontroller, the users can define different states of the switch 11 according to the different conditions. The switch 11 can provide the power or break power to the SoC 20 to control the computer 200. It saves cost of the microcontroller and saves consumption of the electronic power.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A switch device using a computer, the computer comprising a system on chip, the switch device comprising:
a switch;
a power output circuit operable to output a power control signal to the computer;
a control circuit operable to control a power status of the computer;
a timer circuit operable to execute a timer function to the switch device; and
an interface circuit of system on chip operable to connect to a circuit of the system on chip.

2. The switch device of claim 1, wherein the control circuit is electronically connected to the switch, the timer circuit, and the power output.

3. The switch device of claim 1, wherein the control circuit controls the power output circuit to output a power control signal to the system on chip to control the power status of the computer.

4. The switch device of claim 1, wherein the switch comprises a fixed contact point and a moving contact point.

5. The switch device of claim 4, wherein the moving contact point connects the control circuit.

6. The switch device of claim 4, wherein the fixed contact point connects to a first power.

7. The switch device of claim 1, wherein the control circuit comprises a npn type 1, 3 transfer resistor and a npn type 2, 3 transfer resistor.

8. The switch device of claim 7, wherein the npn type 2, 3 transfer resistor connects a capacitor.

9. The switch device of claim 1, wherein the control circuit comprises a npn type 3, 3 transfer resistor.

10. The switch device of claim 1, wherein the timer circuit comprises a resistor and a set of capacitors being in a parallel connection.
